(19) United States
(12) Patent Application Publication
(10) Pub. No.: US 2015/0239093 A1
(43) Pub. Date: Aug. 27, 2015

(54) GRINDING APPARATUS, AND GRINDING METHOD

(71) Applicant: KABUSHIKI KAISHA TOSHIBA, Tokyo (JP)

(72) Inventors: TAKESHI FUKUI, Himeji Hyogo (JP); Kaoru Nakatsuka, Ibo Hyogo (JP); Non Hamada, Ibo Hyogo (JP); Koji Tamura, Himeji Hyogo (JP)

(21) Appl. No.: 14/318,092

(22) Filed: Jun. 27, 2014

(30) Foreign Application Priority Data
Feb. 26, 2014 (JP) 2014-035227

(51) Int. Cl. B24B 49/02; H01L 21/02; H01L 21/66; H01L 21/67

(52) U.S. Cl. CPC B24B 49/02; H01L 21/67092; H01L 21/67253; H01L 21/02013; H01L 22/26

(57) ABSTRACT

According to one embodiment, a grinding apparatus includes a chuck table, a grinding wheel that is pressed against a plurality of separate ground surfaces of a plurality of workpieces fixed to the chuck table while rotating to grind the workpieces, a measuring device that measures heights of the ground surfaces, and a control device that controls amount of grinding of the workpieces based on the heights of the plurality of ground surfaces measured before grinding the workpieces, and the heights of the plurality of ground surfaces measured after grinding the workpieces.

### CROSS-REFERENCE TO RELATED APPLICATION

This application is based upon and claims the benefit of priority from Japanese Patent Application No. 2014-035227, filed Feb. 26, 2014, the entire contents of which are incorporated herein by reference.

### FIELD

Embodiments described herein relate generally to a grinding apparatus, and a grinding method.

### BACKGROUND

Recently, there have been proposed structures using plate-shaped connectors or straps made of copper or the like, as opposed to bonded wires, as structures for connecting semiconductor device chips to external leads of the chip package, in order to reduce resistance in power semiconductor devices.

Also, there has been proposed a structure in which a connector mounted on a chip is exposed from, i.e., uncovered by, the encapsulating or sealing resin such that heat is released from two surfaces, that is, a package bottom surface located on the mounting substrate side, and a package top surface. In order to expose the top surface of the connector from the resin, a method of covering the top surface of the connector with the resin in a resin molding process and grinding the resin is usable.

### DESCRIPTION OF THE DRAWINGS

FIG. 1 is a view schematically illustrating a grinding apparatus according to an embodiment.

FIGS. 2A and 2B are views schematically illustrating the grinding apparatus according to the embodiment.

FIG. 3 is a top view schematically illustrating workpieces according to the embodiment.

FIGS. 4A and 4B are flow charts illustrating a grinding method according to the embodiment.

FIG. 5 is a cross-sectional view schematically illustrating a semiconductor device according to the embodiment.

FIGS. 6A and 6B are top views schematically illustrating the semiconductor device according to the embodiment.

FIGS. 7A and 7B are plan views schematically illustrating a semiconductor chip according to the embodiment.

### DETAILED DESCRIPTION

Embodiments provide a grinding apparatus and a grinding method excellent in controlling the resulting thickness of a ground object or layer on an object.

In general, according to one embodiment, a grinding apparatus includes a chuck table, a grinding wheel that is pressed against a plurality of separate ground surfaces of a plurality of workpieces fixed to the chuck table while rotating to grind the workpieces, a measuring device that measures the height of the ground surfaces, and a control device that controls the amount of grinding of the workpieces based on the height of the plurality of ground surfaces measured before grinding the workpieces, and the height of the plurality of ground surfaces measured after grinding the workpieces.

Hereinafter, an embodiment will be described with reference to the accompanying drawings. In the drawings, components identical to each other are denoted by the same reference symbol.

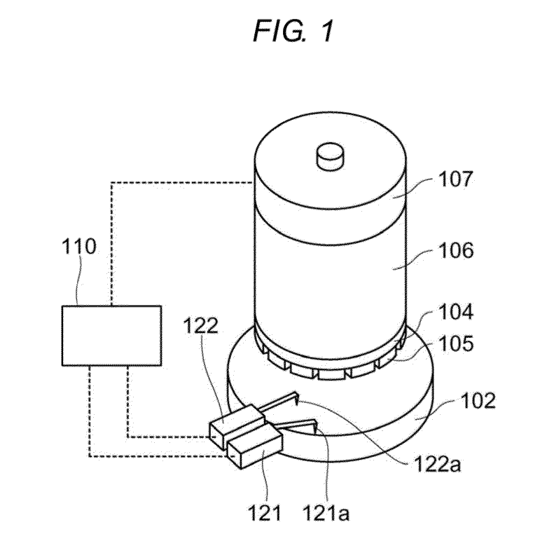

FIG. 1 is a view schematically illustrating a grinding apparatus according to an embodiment.

The grinding apparatus according to the embodiment is, for example, an in-feed type grinding apparatus, and includes a rotating grinding wheel 104, and the apparatus lowers the grinding wheel 104 onto a to-be, or previously, ground object which is connected to, and spinning together with, a chuck table 102, to grind the object.

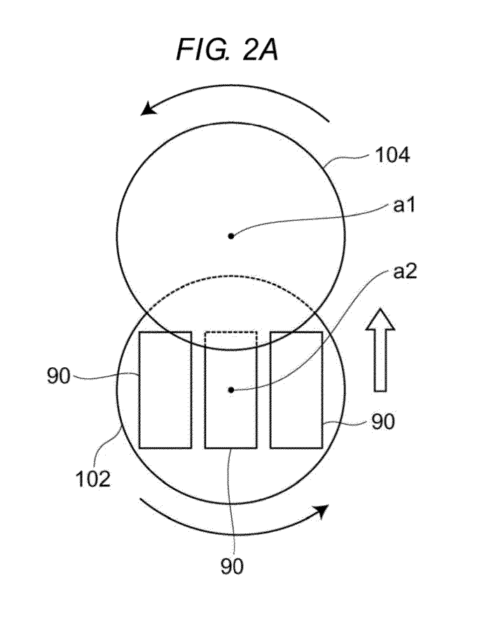

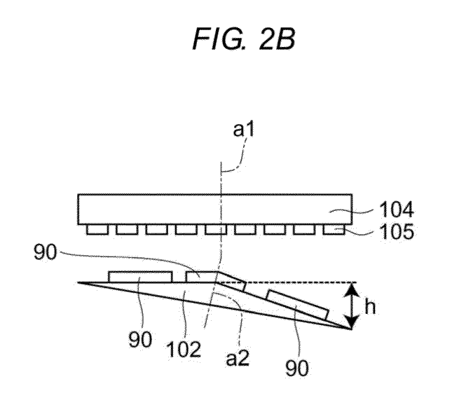

FIG. 2A is a top view schematically illustrating an arrangement relation between the chuck table 102 and the grinding wheel 104.

FIG. 2B is a side view schematically illustrating the arrangement relation between the chuck table 102 and the grinding wheel 104.

The grinding wheel 104 is, for example, a diamond wheel, and on the bottom surface of the grinding wheel 104, a plurality of diamond grindstones 105 are disposed in a ring shaped or circular array.

The grinding wheel 104 is connected to a spindle motor 107 (FIG. 1) through a spindle provided inside a spindle housing 106 (FIG. 1). The spindle motor 107 is usable to rotate the grinding wheel 104 around a rotation axis a1 illustrated in FIGS. 2A and 2B.

Below the grinding wheel 104, the chuck table 102 is provided. The chuck table 102 may move straight in a plane substantially parallel to the rotation surface of the grinding wheel 104.

The chuck table 102 secures a workpiece, such as the to be ground object, by a vacuum chucking system. The workpiece will be described below.

Also, the chuck table 102 may be provided to be able to rotate around a rotation axis a2 illustrated in FIGS. 2A and 2B. In this configuration, the chuck table is very slightly tapered along its upper surface in the form of an outwardly extending cone.

An offset h in height between the central portion and the peripheral portion at the top surface of the chuck table 102 may cause different momenta to be applied to center side workpieces and peripheral side workpieces during grinding thereof, resulting in variations of the thicknesses of the workpieces after grinding. Also, in FIG. 2B, the height offset of the top surface of the chuck table 102 is exaggeratedly illustrated. However, the height offset h is about 30 μm.

According to the embodiment, where the rotation axis a2 of the chuck table 102 is inclined with respect to the rotation axis a1 of the grinding wheel 104, whereby the inclination angle of the rotation axis a2 of the chuck table 102 is adjusted such that the top surface of the chuck table 102 becomes generally parallel to the rotation surface of the grinding wheel 104. Therefore, an area of the workpieces with which the grinding wheel 104 comes into contact with is restricted to the partial area. Therefore, it is possible to reduce the load on the spindle motor 107 during processing, thereby achieving stable processing, and it is possible to suppress variations of thicknesses in the workpieces after grinding.

Also, the grinding apparatus according to the embodiment includes thickness measuring devices 121 and 122 illustrated in FIG. 1. The thickness measuring device 122 includes a measuring head 122a for measuring the position of the ground surface of a workpiece. The thickness measuring device 121 includes a measuring head 121a for measuring the position of the peripheral portion of the top surface of the chuck table 102. Based on the difference between the position of the ground surface of the workpiece and the position of the top surface of the chuck table 102 or the upper surface of a sheet on the chuck table on which a plurality of individual workpieces are held for grinding, the thickness of the workpiece may be determined, and monitored during the grinding away of a surface thereof.

Further, the grinding apparatus according to the embodiment includes a control device 110. The control device 110 controls driving of the spindle motor 107, lifting and lowering of the grinding wheel 104 which may be accomplished by gearing and actuators within housing 106, or by a lowering and lifting apparatus located externally and above the spindle motor 107, linear movement reciprocally along the arrow of FIG. 2A and rotation of the chuck table 102, and the like. Also, the control device 110 controls operations of the above described components based on the measured results of the thickness measuring devices 121 and 122, thereby controlling the ground or removed amount of the workpiece such that the thickness of the workpiece becomes a desired specified thickness.

Hereinafter, a semiconductor device will be described as an example of a workpiece which is a grinding object.

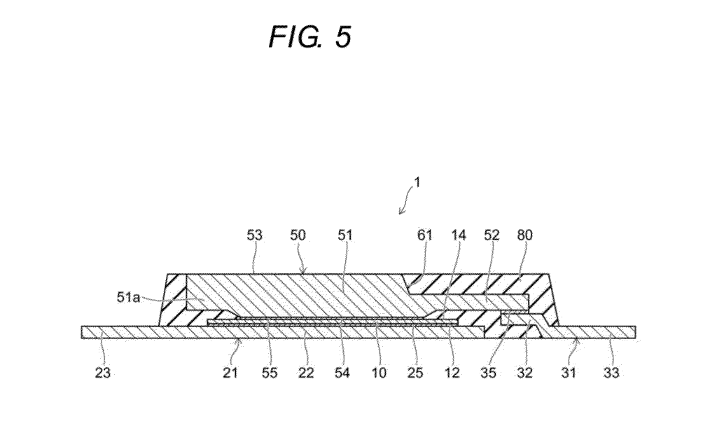

FIG. 5 is a cross-sectional view schematically illustrating a semiconductor device 1 according to the embodiment.

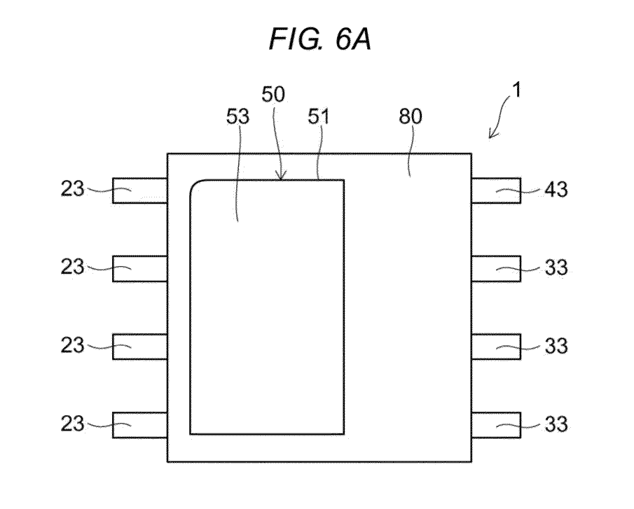

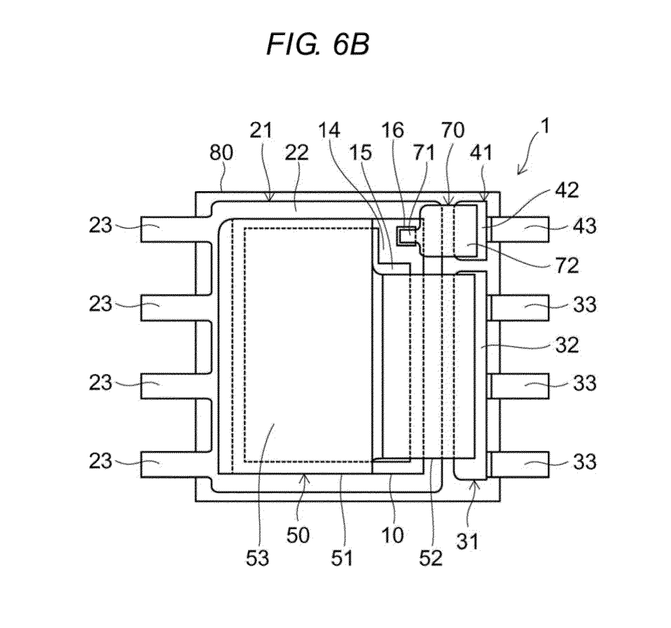

FIG. 6A is a top view schematically illustrating the semiconductor device 1, and FIG. 6B is a top view schematically illustrating the semiconductor device 1 with resin 80 absent. In FIG. 6B, only a line representing the perimeter of the resin 80 is illustrated.

The semiconductor device 1 includes a semiconductor chip 10, lead frames 21, 31, and 41 electrically connected to the semiconductor chip 10, a first connector 50, a second connector 70, and the resin 80 sealing these components.

The semiconductor chip 10 is a vertical type device having a first electrode provided on one surface side of a semiconductor layer, a second electrode provided on the other surface side of the semiconductor layer, and a current path formed in a vertical direction so as to connect the first electrode and the second electrode. The semiconductor chip 10 is, for example, a vertical type Metal-Oxide-Semiconductor Field Effect Transistor (MOSFET). Alternatively, the semiconductor chip 10 may be a vertical type Insulated Gate Bipolar Transistor (IGBT), or a vertical type diode.

As a semiconductor, silicon may be used. Alternatively, a semiconductor (for example, a compound semiconductor such as SiC or GaN) other than silicon may be used.

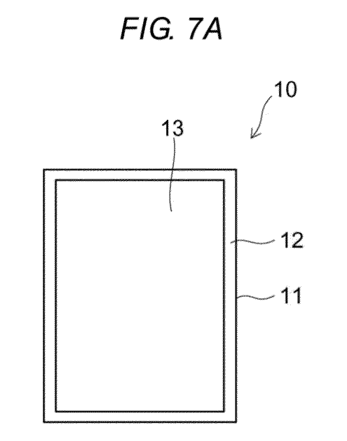

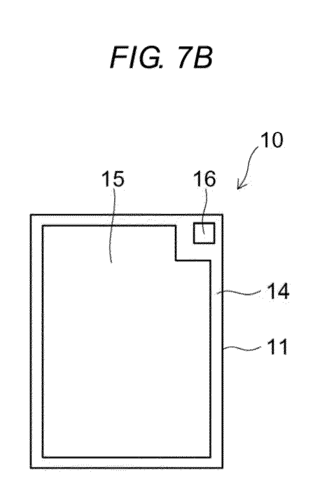

FIG. 7A is a plan view schematically illustrating a first surface 12 of the semiconductor chip 10, and FIG. 7B is a plan view schematically illustrating a second surface 14 which is the opposite side to the first surface 12.

As illustrated in FIG. 7A, on the first surface 12 of a semiconductor layer 11, a first electrode 13 is formed. For example, in a MOSFET, the first electrode 13 is a drain electrode. The first electrode 13 is formed over most of the first surface 12.

As illustrated in FIG. 7B, on the second surface 14 of the semiconductor layer 11, a second electrode 15 and a third electrode 16 are formed so as to be insulated from each other. The second electrode 15 is formed over most of the second surface 14, and for example, in a MOSFET, the second electrode 15 is a source electrode. The area of the third electrode 16 is smaller than the area of the second electrode 15, and for example, in a MOSFET, the third electrode 16 is a gate electrode.

As illustrated in FIG. 6B, the first lead frame 21 includes a die pad 22, and a plurality of leads 23. The die pad 22 is formed such that the planar shape thereof is quadrangular, i.e., four sided, and in the embodiment shown in FIGS. 6A and 6B, rectangular or square shaped in perimeter, and the plurality of leads 23 extend from one side of the die pad 22. The first lead frame 21 is formed by stamping or punching of a metal plate into the shape of first lead frame 21, and the die pad 22 and the leads 23 are thus integrally formed therewith.

On the side of the semiconductor device 1 opposed to the protruding direction of the leads 23 of the first lead frame 21, the second lead frame 31 is separately provided and spaced from the first lead frame 21.

The second lead frame 31 includes an inner lead 32 provided on the first lead frame 21 side, and a plurality of outer leads 33 protruding from the inner lead 32. The outer leads 33 protrude from the second lead frame 31 in the direction opposed to the protruding direction of the leads 23 of the first lead frame 21. The inner lead 32 extends from the second lead frame 31 in a direction opposed to the protruding direction of the outer leads 33 and in the protruding direction of the leads 23 of the first lead frame 21.

The second lead frame 31 is formed by stamping or punching of a metal plate into the shape of second lead frame 31, and the inner lead 32 (FIG. 5) and the outer leads 33 are thus integrally formed therewith.

Also, on the side of the semiconductor device 1 opposed to the protruding direction of the leads 23 of the first lead frame 21 and spaced therefrom, and adjacent to but spaced from the second lead frame 31, the third lead frame 41 is provided. The third lead frame 41 is provided next to the inner lead 32 of the second lead frame 31 in the longitudinal direction of the inner lead 32 of the second lead frame 31. The third lead frame 41 is separately provided and spaced from the first lead frame 21 and the second lead frame 31.

The third lead frame 41 includes an inner lead 42 extending therefrom in the direction of the first lead frame 21, and an outer lead 43 protruding from the third lead frame 42 in the same direction as the protruding direction of the outer leads 33 of the second lead frame 31.

As illustrated in FIG. 5, no step is formed between the leads 23 and die pad 22 of the first lead frame 21. That is, the top surfaces of the leads 23 and the top surface of the die pad 22 are generally co-planar, and the bottom surfaces of the leads 23 and the bottom surface of the die pad 22 are generally co-planar.

The second lead frame 31 is bent at a portion thereof between the inner lead 32 and the outer leads 33, whereby a step is formed between the inner lead 32 and the outer leads 33. Similarly to the second lead frame 31, the third lead frame 41 is also bent at a portion thereof between the inner lead 42 and the outer lead 43, whereby a step is formed between the inner lead 42 and the outer lead 43.

The bottom surfaces of the outer leads 33 of the second lead frame 31 are flush with, i.e., they extend generally co-planar with, the bottom surface of the first lead frame 21 (the bottom surfaces of the leads 23 and the bottom surface of the die pad 22). The bottom surface of the outer lead 43 of the third lead frame 41 is flush with i.e., it extends generally co-planar with, the bottom surface of the first lead frame 21 and the bottom surfaces of the outer leads 33 of the second lead frame 31.

If the bottom surfaces of the outer leads 33 and 43 and the bottom surface of the first lead frame 21 are set as a reference location or position of a height direction (a vertical direction), the top surfaces of the inner leads 32 and 42 are positioned higher than the top surface of the die pad 22.

The semiconductor chip 10 is mounted on the die pad 22 of the first lead frame 21. The semiconductor chip 10 is mounted such that the first surface 12 having the first electrode 13 formed thereon is positioned facing, and electrically bonded to, the die pad 22 side.

The first electrode 13 is bonded to the die pad 22 by a conductive bonding material (for example, solder) 25 illustrated in FIG. 5. Therefore, the first electrode 13 of the semiconductor chip 10 is electrically connected to the first lead frame 21.

On the second surface 14 of the semiconductor chip 10, the plate-shaped first connector (a source connector in a MOSFET) 50 is mounted. The first connector 50 includes a first portion 51 positioned over, and electrically connected to, the second electrode 15 on the second surface 14 of the semiconductor chip 10, and a second portion 52 extending therefrom in the direction of the second lead frame 31 and terminating over the second lead frame 31. The first portion 51 and the second portion 52 have relatively different thicknesses, and the first portion 51 is thicker than the second portion 52.

The first connector 50 is formed by stamping or punching a metal plate to integrally form the first portion 51 and the second portion 52. For example, the first connector 50 is made of copper having excellent electric conduction and heat conduction properties. The first connector 50 may also be made of a copper alloy containing copper as a main component.

The first portion 51 is thicker than each of the lead frames 21, 31, and 41, and for example, the thickness of the first portion 51 is equal to or larger than 0.5 mm and equal to or smaller than 1 mm. The first portion 51 has a bonded surface 54 bonded to the second electrode 15 of the semiconductor chip 10 by a conductive bonding material 55 such as solder. Also, the first portion 51 has a heat radiating surface 53 formed on the opposite side to the bonded surface 54 and exposed from, i.e., not covered by, the resin 80.

The second portion 52 protrudes from the first portion 51 toward the second lead frame 31. The end portion of the second portion 52 overlaps the top of the inner lead 32 of the second lead frame 31, and is bonded to the top surface of the inner lead 32 by a conductive bonding material 35 such as solder.

Therefore, the first connector 50 is electrically connected to the second electrode 15 of the semiconductor chip 10 and the second lead frame 31.

Also, as illustrated in FIG. 6B, the third electrode (gate electrode) 16 of the semiconductor chip 10, and the third lead frame 41 are electrically connected by the second connector (a gate connector in a MOSFET) 70. Alternatively, the third electrode (gate electrode) 16 and the third lead frame 41 may be connected by wire bonding.

One end portion 71 of the second connector 70 is bonded to the third electrode 16 on the second surface 14 of the semiconductor chip 10 by a conductive bonding material such as solder. The other end portion 72 of the second connector 70 overlaps the top of the inner lead 42 of the third lead frame 41, and is bonded to the top surface of the inner lead 42 of the third lead frame 41 by a conductive bonding material such as solder. The second connector 70 is made of, for example, copper or a copper alloy.

Also, the above described conductive bonding material is not limited to solder, and may be conductive paste such as silver paste.

The semiconductor chip 10 is sealed by the resin 80, thereby being protected from the external environment. The resin 80 covers the semiconductor chip 10, the top surface of the die pad 22 not covered by the semiconductor chip 10, the inner lead 32 of the second lead frame 31, the inner lead 42 of the third lead frame 41, the side surface of the first portion 51 of the first connector 50, the second portion 52 of the first connector 50, and the second connector 70.

Also, the resin 80 covers the bonding portion of the first surface 13 and the die pad 22 where the bonding surface is not covered by the semiconductor chip 10, the bonding portion of the second electrode 15 where it is not covered by the first connector 50, the interface of the second portion 52 of the first connector 50 and the inner lead 32 of the second lead frame 31, the interface of the third electrode 16 and the second connector 70, and the interface of the second connector 70 and the inner lead 42 of the third lead frame 41.

The bottom surface of the first lead frame 21 (the bottom surfaces of the leads 23 and the bottom surface of the die pad 22), the bottom surfaces of the leads 33 of the second lead frame 31, and the bottom surface of the lead 43 of the third lead frame 41 are not covered with the resin 80 so as to be exposed from, i.e., not covered by, the resin 80.

The bottom surface of the first lead frame 21, the bottom surfaces of the outer leads 33 of the second lead frame 31, and the bottom surface of the outer lead 43 of the third lead frame 41 are ultimately bonded to a conductor pattern of the mounting substrate (wiring substrate) (not illustrated), for example, by solder.

Also, as illustrated in FIGS. 5 and 6A, the top surface of the first portion 51 of the first connector 50 is exposed from, i.e. not covered by, the resin 80, and functions as a heat radiating surface 53. If necessary, a heat sink may be bonded to the heat radiating surface 53 of the first connector 50.

Heat generated in the semiconductor chip 10 is radiated to the mounting substrate through the die pad 22 having an area larger than that of the first electrode 13, and is also transferred to the outside of the semiconductor chip 10 (for example, into the air) through the heat radiating surface 53 of the first connector 50. That is, the semiconductor device 1 according to the embodiment has a package structure capable of transferring heat from both sides, and thus may improve heat transfer and removal performance, particularly, in a case of a power application in which the amount of heat generated by the semiconductor chip 10 is likely to be large.

The first portion 51 of the first connector 50 electrically connects the semiconductor chip 10 and the second lead frame 31, and also functions as a heat radiator for transfer heat toward the opposite direction as that of the mounting surface. The first portion 51 of the first connector 50 is mounted directly on the semiconductor chip 10, and the ratio of the area of the bonded surface of the second electrode 15 and the first portion 51 to the area of the second electrode 15 of the semiconductor chip 10 is 80% or more. Also, the ratio of the heat radiating surface 53, i.e., the exposed surface of the first portion 51 of the first connector 50 to the area of the second electrode 15 of the semiconductor chip 10 is 100% or more, i.e., the exposed area of surface 53 is at least as large, or larger than, the area of contact between first portion 51 and the second electrode 15 of the semiconductor chip 10 via the conductive bonding material 55.

That is, most of the surface of the second electrode 15 is used as a surface for conducting heat to the first connector 50, and heat conducted to the first connector 50 is radiated, i.e., transferred via convection, conduction or radiation, from the heat radiating surface 53 having an area equal to or larger than that of the second electrode 15 to the outside of the semiconductor device 1. Therefore, it is possible to effectively use the first connector 50 as a heat radiator, and thus the semiconductor device 1 is excellent in heat transfer and removal efficiency.

The first connector 50 is not formed such that the whole first connector 50 is thick, and the second portion 52 thinner than the first portion 51 is provided, whereby an area to be covered from the top surface side of the first connector 50 with the resin 80 is provided. That is, at the second portion 52, the resin 80 covers the top surface of the first connector 50. Therefore, the second portion 52 is buried in the resin 80. Therefore, as compared to a structure in which the entire top surface of the first connector 50 is exposed from the resin 80, it is possible to suppress peeling off of the resin 80 (the resin 80 coming off of the first connector 50).

According to the embodiment, in the process of molding the resin 80 over the semiconductor chip 10, the lead frames 21, 31 and 41 and connectors 50, 70, the top surface (the heat radiating surface 53) of the first connector 50 is initially covered with the resin 80. Thereafter, the resin 80 is ground by the above described grinding apparatus, whereby the heat radiating surface 53 is exposed.

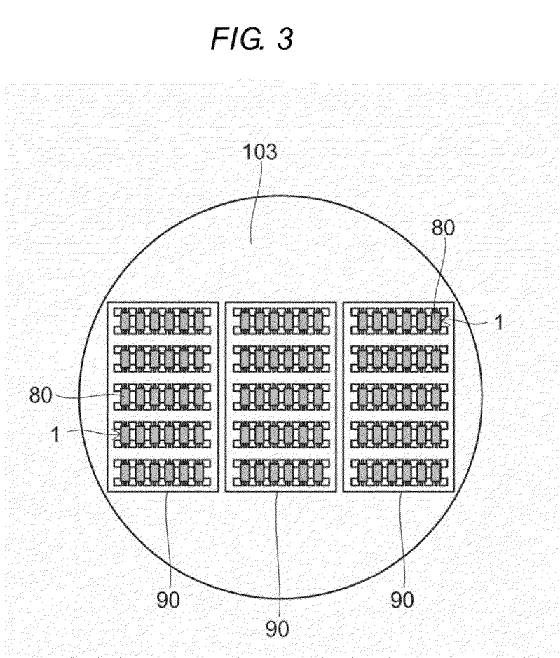

FIG. 3 is a top view schematically illustrating semiconductor devices 1 set on the chuck table 102 before grinding.

The individual lead frames 21, 31 and 41 are cut from a frame 90, whereby a plurality of semiconductor chips 10 are bonded to the frame in a spaced arrangement, the portions of the frame corresponding to each semiconductor device 1 to be recovered therefrom is encapsulated in the resin 80, and thereafter individual devices 1, having the configuration of FIGS. 5, 6A and 6B are cut therefrom. The frames may be several feet in length, and have several hundred individual semiconductor devices ready to be cut therefrom. In that case, a smaller segment of the frame 90 may be cut from the several foot long frame, for further processing of the packaging and resin 80 prior to singulation of individual semiconductor devices therefrom.

Prior to cutting individual semiconductor devices from the frames 90, a plurality of (for example, three in FIG. 3) frames 90, each having 6 semiconductor devices 1 thereon, are attached to an adhesive sheet 103. The adhesive sheet 103 is fixed to the top surface of the above described chuck table 102. Therefore, on the chuck table 102, a plurality of ground surfaces (resins 80) of a plurality of workpieces (semiconductor devices 1) are disposed separately from one another.

Since the plurality of frames 90 are attached to one adhesive sheet 103, it is possible to reduce the cost of intermediate materials such as the adhesive sheet 103 for grinding, and the processing time.

Unlike general wafer grinding, the surfaces (upper surface of resin 80) to be ground are discontinuous on the adhesive sheet 103. Therefore, in a state where the plurality of to be ground surfaces (upper surface of resin 80) are attached to the adhesive sheet 103 before the grinding, variations are likely to occur in the heights of the plurality of ground surfaces (resins 80) due to variation occurring when the frames 90 are attached to the adhesive sheet 103, the thickness variation of the adhesive sheet 103, the thickness variation of the frames 90 based on tolerances of dies forming the frames 90, or the like.

Here, as a comparative example, if the height of a ground surface is measured only at one point, and the amount of grinding is controlled based on the measured value, in a case where the height of the top surface of the resin 80 of the semiconductor device 1 which is the measuring object is considerably different from the heights of the top surfaces of the resins 80 of the other semiconductor devices 1, grinding is like to be excessively or insufficiently performed on the plurality of ground objects viewed as a whole.

For this reason, according to the embodiment, the heights of the to be ground surfaces (resin 80) are measured at a plurality of positions, and the amount of grinding of the resin 80 is controlled, for example, based on the average value, maximum value, or minimum value of the plurality of measured values.

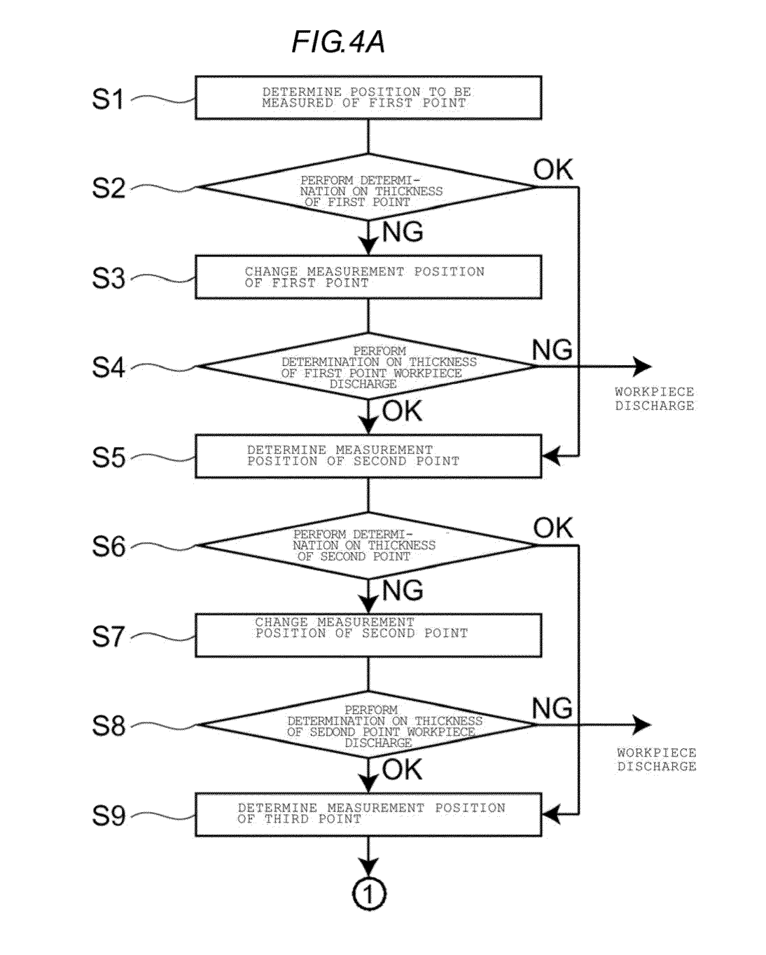

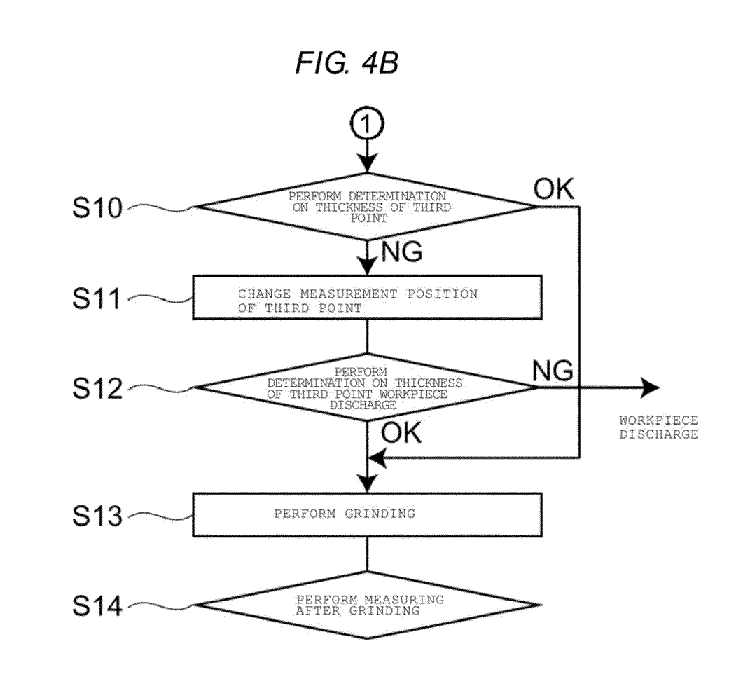

FIGS. 4A and 4B are flow charts illustrating a grinding method according to the embodiment.

In the following description, not only before grinding but also after grinding, for example, the heights of three points on the sheet corresponding to three different frames 90 are measured. Of course, the number of points is not limited to three. Not only before grinding but also after grinding, the heights of two points or four or more points may be measured.

STEPS S1 to S12 represent the flow of height measuring before grinding.

First, in STEP S1, a position to be measured of a first point is determined. The in-plane positions of the measuring heads 121a and 122a are fixed, and the measuring heads 121a and 122a move only vertically. The chuck table 102 performs linear movement reciprocally along the path shown by the large arrow above reference number 90 in FIG. 2A and rotation, whereby the measuring heads 121a and 122a are positioned at object measuring positions. As a result, it becomes possible to measure a plurality of points by a stable system having low time loss.

The measuring head 121a measures the height of the peripheral portion of the top surface of the chuck table 102, and the measuring head 122a measures the height of one ground surface (resin 80) selected from the ground surfaces (resins 80) of the plurality of semiconductor devices 1 illustrated in FIG. 3. Based on the measured results, the thickness of the corresponding semiconductor device 1, including the thickness of the resin thereon, is obtained.

Subsequently, in STEP S2, determination on the measured value (thickness) of the first point is performed. For example, due to shift of the attachment position of a frame 90 with respect to the adhesive sheet 103, or the like, it may be impossible to accurately measure a to be ground object (the height of the top surface of a resin 80). For this reason, in a case where the measured value of the first point is out of a predetermined standard range, for example, the measured value is equal to or smaller than 400 the flow proceeds to STEP S3 in which the position to be measured is changed.

The chuck table 102 is rotated from the position to be measured where an error has occurred, by an arbitrary angle, whereby the position to be measured is changed. With the rotation of the chuck table 102, the measuring heads 121a and 122a relatively move in a circumferential direction with respect to the top surface of the chuck table 102. Then, at positions to which the measuring heads 121a and 122a have moved, re-measurement of the first point is performed.

Thereafter, in STEP S4, determination on the measured value is performed similarly in STEP S2. Here, in a case where the measured value is also out of the standard range, the workpiece, i.e., the sheet 103 having a plurality of frames 90 thereon is removed from the grinding apparatus. Alternatively, the position to be measured may be changed again and re-measurement may be performed. The number of times of measured-value determination and re-measurement may be arbitrarily set. The measured value determination makes it possible to detect abnormalities in attachment of the workpiece to the adhesive sheet 103.

In a case where abnormality is not detected in the measured value determination of STEP S2 or S4, the flow proceeds to STEP S5 in which height measurement of a second point is performed.

In STEP S5, the chuck table 102 is rotated from the position to be measured of the first point (in a case where re-measurement has been performed, the re-measurement position), by a user selected angular change, whereby the measuring heads 121a and 122a are positioned at positions to be measured of the second point.

With the rotation of the chuck table 102, the measuring heads 121a and 122a relatively move in the circumferential direction with respect to the top surface of the chuck table 102. Then, at positions to which the measuring heads 121a and 122a have moved, measurement of the second point is performed.

The measuring head 121a moves along the peripheral portion of the top surface of the chuck table 102, and measures the height of the peripheral portion of the chuck table 102 again in measuring the second point.

The measuring head 122a is positioned on the resin 80 of a semiconductor device 1 different from that measured during the measurement of the first point, and measures the height of the top surface of the corresponding resin 80.

When measuring the second point, in STEP S6, determination of the usefulness of the measured value is performed similarly to that determination in the measurement of the first point. In a case where the measured value of the second point is out of the standard range, re-measurement (STEP S7) and determination on the re-measured value (STEP S8) are performed.

In a case where it is determined in STEP S8 that the re-measured value is out of the standard range, the workpiece is discharged from the grinding apparatus. Alternatively, the position to be measured may be changed again and re-measurement may be performed. The number of times of measured-value determination and re-measurement may be arbitrarily set.

In a case where abnormality is not detected in the measured-value determination of STEP S6 or S8, the flow proceeds to STEP S9 in which height measurement of a third point is performed.

In STEP S9, the chuck table 102 is rotated from the position to be measured of the second point (in a case where re-measurement has been performed, the re-measurement position), by an arbitrary angle, whereby the measuring heads 121a and 122a are positioned at positions to be measured of the third point.

With the rotation of the chuck table 102, the measuring heads 121a and 122a relatively move in the circumferential direction with respect to the top surface of the chuck table 102. Then, at positions to which the measuring heads 121a and 122a have moved, measurement of the third point is performed.

The measuring head 121a moves along the peripheral portion of the top surface of the chuck table 102, and measures the height of the peripheral portion of the chuck table 102 again in measuring the third point.

The measuring head 122a is positioned on the resin 80 of a semiconductor device 1 different from those measured during the measurement of the first point and the second point, and measures the height of the top surface of the corresponding resin 80.

When measuring the third point, in STEP S10, determination of the usefulness of the measured value is performed similarly to that of the measurement of the first point and the second point. In a case where the measured value of the third point is out of the standard range, re-measurement (STEP S11) and determination on the re-measured value (STEP S12) are performed.

In a case where it is determined in STEP S12 that the re-measured value is out of the standard range, the workpiece is discharged from the grinding apparatus. Alternatively, the position to be measured may be changed again and re-measurement may be performed. The number of times of measured-value determination and re-measurement may be arbitrarily set.

In a case where abnormality is not detected in the measured-value determination of STEP S10 or S12, the flow proceeds to STEP S13 in which grinding of the resin 80 on the frames 90 is performed.

During grinding, the grinding wheel 104 and the chuck table 102 are rotated in the same direction, and the grinding wheel 104 is lowered with respect to the chuck table 102, whereby the grindstones 105 on the grinding wheel are pressed against the resins 80.

The measured results of the heights of a plurality of points (for example, three points) before grinding are fed back for controlling an amount of grinding (a grinding time at a specific grinding pressure) during grinding. For example, based on the average value, maximum value, or minimum value of the measured values of three points, the amount of grinding (the grinding time) is controlled, and the amount of grinding (grinding time) of the resins 80 is controlled such that the top surfaces (heat radiating surfaces) 53 of the above described connectors 50 are exposed. Also, after the heat radiating surfaces 53 are exposed from the resins 80, the heat radiating surfaces 53 may be further ground such that the thickness or height of the plurality of semiconductor devices 1 are controlled to a predetermined height or thickness.

Since the measured values of the heights of a plurality of points before grinding are fed back for controlling the amount of grinding, it is possible to suppress height variations in the semiconductor devices 1 after grinding, as compared to a case of using only the measured value of the height of one point on one device.

After grinding, in STEP S14, the heights of the same positions as the positions of the three points measured before grinding are again measured. In a case where re-measurement has been performed before grinding, after grinding the height of the same position as the corresponding re-measurement position is measured. Since the heights of the same positions are measured before and after grinding, it is possible to accurately compute the amount of resin, i.e., the amount of material removed, by the grinding operation.

Thereafter, based on the measured results of the heights of the plurality of points (three points) after grinding (for example, the average value, maximum value, or minimum value of the measured values of the three points), it is determined whether the thicknesses of the semiconductor devices 1 are equal to or smaller than a specified value. In a case where the thicknesses of the semiconductor devices 1 exceed the specified value due to insufficiency in the amount of grinding of the resin 80, re-grinding is performed. In this case, the measured results after grinding are fed back for controlling the amount of re-grinding.

In the case where the measured results after grinding exceed a specified value, based on determination and control of the control device 110, re-grinding is automatically performed. Until the measured values after grinding become equal to or smaller than the specified value, grinding, and measuring after grinding are automatically repeated.

Even if a plurality of grinding steps for converging the workpiece heights to a target value is necessary due to the kind of workpieces, an attachment state, or the like, re-grinding and re-measurement may be automatically performed. Therefore, it is possible to shorten the process time and reduce the cost of grinding.

According to the embodiment, since determination of the thicknesses of the semiconductor devices 1 is performed based on the measured values of a plurality of points before and after grinding, it is possible to suppress variations in the resulting device 1 thicknesses and thus accurately control the thicknesses of the semiconductor devices 1.

Also, it is possible to use the measured results of the plurality of points after grinding to detect abnormalities in the grinding operation.

During grinding, the grinding wheel 104 is first lowered at a high speed with respect to the chuck table 102, and as the grinding wheel 104 becomes close to the chuck table 102, the grinding wheel 104 is slowed down and is brought close to workpieces, whereby the grindstones 105 are brought into contact with the workpieces. Therefore, it is possible to reduce impact on the workpieces upon contact while shortening the index time.

At the transmission (deceleration) timing of the lowering speed of the grinding wheel 104 of that case, it is possible to feed back the measured values before initiating the grinding of the resin. For example, if the deceleration timing of the grinding wheel 104 is controlled based on the maximum value of the measured values of the three points before grinding, the grinding wheel 104 may be reliably prevented from coming into contact with the workpieces at a high speed by initiating deceleration prior to engagement with the thickest of the devices 1.

Also, measurement of the first point after the grinding is performed does not start immediately after grinding, and a delay time is set until oscillation (vibration) of the workpieces stops. Since measuring is performed after an appropriate delay time elapses after grinding, it is possible to improve the measurement accuracy. Also, it is possible to prevent workpieces from being damaged by the measuring head 122a.

Also, since a delay time until oscillation (vibration) of the workpieces stops after rotation of the chuck table 102 for changing the position to be measured is set, it is possible to improve the measurement accuracy, and to prevent damage of the workpieces.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A grinding apparatus comprising:
a chuck table;
a grinding wheel configured to be pressed against a surface of a plurality of workpieces individually fixed to the chuck table while rotating, to grind a surface of the workpieces;
a measuring device configured to measure the height of at least two of the surfaces prior to and after grinding thereof; and
a control device configured to control a depth of grinding of the workpieces based on the individual heights of the plurality of ground surfaces measured before grinding of the workpieces, and the individual heights of the plurality of ground surfaces measured after grinding of the workpieces.

2. The grinding apparatus according to claim 1, wherein
the number of points at which the height is measured before grinding is the same as that after grinding.

3. The grinding apparatus according to claim 1, wherein
the location of the points at which the height is measured before grinding is the same location as the location measured after grinding.

4. The grinding apparatus according to claim 1, wherein
the control device is configured to compare an average value of the heights of the plurality of points measured before grinding, with an average value of the heights of the plurality of points measured after grinding.

5. The grinding apparatus according to claim 1, wherein
the control device is configured to compare a maximum value of the heights of the plurality of points measured before grinding, with a maximum value of the heights of the plurality of points measured after grinding.

6. The grinding apparatus according to claim 1, wherein
the control device is configured to compare a minimum value of the heights of the plurality of points measured before grinding, with a minimum value of the heights of the plurality of points measured after grinding.

7. The grinding apparatus according to claim 1, wherein
when a value of height measured before grinding is out of a standard range, the control device is configured to change the measuring location, and measures the height again at the different location.

8. The grinding apparatus according to claim 1, wherein the workpiece includes a heat sink encapsulated in resin before the grinding is performed, and a surface of the heat sink is exposed after the grinding is completed.

9. A method of grinding a plurality of workpieces fixed to a chuck table by pressing a rotating grinding wheel against the plurality of separate ground surfaces of the workpieces, comprising:
before grinding the workpieces, measuring the height of a plurality of the workpieces fixed to the chuck table, and after grinding the workpieces, measuring the height of a plurality of ground surfaces of the workpieces fixed to the chuck table, and
based on the measured heights of the plurality of ground surfaces as measured before and after grinding of the workpieces, controlling an amount of material removed from the workpieces.

10. The method of claim 9, wherein
the workpieces each include a lead frame, a semiconductor chip provided on the lead frame, a plate-shaped connector provided on the semiconductor chip, and resin covering the semiconductor chip and the connector, and
the resin overlying the connector is ground away to expose a top surface of the connector.

11. The method of claim 9, wherein the controlling an amount of material removed from the workpieces includes comparing the measured heights of the plurality of ground surfaces as measured before and after grinding of the workpieces; and
determining whether a finished height of the workpieces has been reached.

12. The method of claim 11, wherein if the finished height has not been reached, further grinding the workpieces.

13. The method of claim 9, wherein the measuring of the height of a plurality of the work pieces before grinding the workpieces, and the measuring the height of the workpieces after grinding the workpieces, is performed on the same workpieces.

14. The method of claim 12, wherein, after the workpieces are further ground, measuring the height of a plurality of again ground surfaces of the workpieces, and
based on the measured heights of the plurality of ground surfaces as measured before grinding and after again grinding of the workpieces, determining whether a finished thickness has been reached, and, if a finished thickness is reached, removing the ground workpieces.

15. The method of claim 10, wherein a portion of the surface of the plate shaped connector exposed by grinding of the resin is ground away during the grinding operation.

16. A material removal apparatus, comprising:
a chuck table configured to receive a sheet having a plurality of individual workpieces thereon;
a material removal element configured to be lowered and raised with respect to the chuck;
a measuring device configured to measure the height of individual workpieces on the sheet, and
a control device configured to control an amount of material removed from the workpieces based on the difference in height of a plurality of workpieces measured before and after performance of a material removal step thereof.

17. The material removal apparatus of claim 16, wherein the material removal element includes a plurality of grinding elements thereon.

18. The material removal apparatus of claim 16, wherein the material removal element is configured to be lowered at a first speed and a second speed, the second speed occurring as the material removal elements engages the workpieces.

19. The material removal apparatus of claim 18, wherein the a control device is further configured to control the lowering speed of the grinding material element based upon the measured height of the workpieces.

20. The material removal apparatus of claim 19, wherein:
the workpieces each include a lead frame, a semiconductor chip provided on the lead frame, a plate-shaped connector provided on the semiconductor chip, and resin covering the semiconductor chip and the connector, and
the material removal apparatus is configured to remove the resin overlying the connector to expose a top surface of the connector therein.
